(19) United States
(12) Patent Application Publication
(10) Pub. No.: US 2026/0165192 A1
(43) Pub. Date: Jun. 11, 2026

(54) METHOD FOR MANUFACTURING SEMICONDUCTOR DEVICE AND SEMICONDUCTOR DEVICE

(71) Applicant: Mitsubishi Electric Corporation, Tokyo (JP)

(72) Inventor: Takumi HAMADA, Tokyo (JP)

(73) Assignee: Mitsubishi Electric Corporation, Tokyo (JP)

(21) Appl. No.: 19/302,570

(22) Filed: Aug. 18, 2025

(30) Foreign Application Priority Data
Dec. 6, 2024 (JP) 2024-213282

(51) Int. Cl. H01L 23/31; H01L 21/027; H10D 62/83; H10D 62/832; H10D 62/85

(52) U.S. Cl. CPC H10W 74/137; H10D 62/8303; H10D 62/8325; H10D 62/8503; H10P 76/202

(57) ABSTRACT

A method for manufacturing a semiconductor device according to the present disclosure includes; forming an electrode on a main surface of a semiconductor substrate having the main surface and a rear surface opposite to the main surface; forming a first protective film on the electrode and the semiconductor substrate; forming a second protective film on the first protective film; patterning a portion of the second protective film formed directly above an exposed portion including a portion of the electrode or a portion of the semiconductor substrate to partially expose a portion of the first protective film formed directly above the exposed portion from the second protective film; processing the rear surface of the semiconductor substrate; and removing the patterned portion of the second protective film together with the portion of the first protective film formed directly above the exposed portion, to expose the exposed portion.

### BACKGROUND

### Field

The present disclosure relates to a method for manufacturing a semiconductor device and a semiconductor device.

### Background

JP 2005-26428 A discloses a method for manufacturing a semiconductor device. In this manufacturing method, a surface structure of a semiconductor device is created on the surface of a semiconductor wafer, and the surface of the semiconductor wafer is covered with a protective film, except for areas of the surface structure to which wires are fixed during mounting. Next, the rear surface of the semiconductor wafer covered with the protective film is ground. When grinding the rear surface, an adhesive tape is attached to the surface of the semiconductor wafer.

In JP 2005-26428 A, the rear surface of the semiconductor substrate is ground to obtain a desired thickness. In this case, it is necessary to cover the surface of the semiconductor substrate with a protective film such as an adhesive tape so as to prevent the surface from being scratched during grinding. This protective film is removed after processing of the rear surface of the semiconductor substrate is completed. There has been a demand for simplifying the process of forming and removing such a protective film to reduce material costs and manufacturing time.

### SUMMARY

The present disclosure has been made to solve the above-mentioned problems, and has an object to provide a semiconductor device and a method for manufacturing thereof that can simplify the manufacturing process.

The features and advantages of the present disclosure may be summarized as follows.

According to an aspect of the present disclosure, a method for manufacturing a semiconductor device includes; forming an electrode on a main surface of a semiconductor substrate having the main surface and a rear surface opposite to the main surface; forming a first protective film on the electrode and the semiconductor substrate; forming a second protective film on the first protective film; patterning a portion of the second protective film formed directly above an exposed portion including a portion of the electrode or a portion of the semiconductor substrate to partially expose a portion of the first protective film formed directly above the exposed portion from the second protective film; after the patterning of the second protective film, processing the rear surface of the semiconductor substrate; and after the processing of the rear surface of the semiconductor substrate, removing the patterned portion of the second protective film together with the portion of the first protective film formed directly above the exposed portion, to expose the exposed portion from the first protective film and the second protective film.

According to an aspect of the present disclosure, a semiconductor device includes a semiconductor substrate having a main surface and a rear surface opposite to the main surface; an electrode formed on the main surface of the semiconductor substrate; a first protective film formed on the electrode and the semiconductor substrate; and a second protective film formed on the first protective film; wherein an exposed portion is formed in a portion of the electrode or a portion of the semiconductor substrate, the exposed portion being exposed from the first protective film and the second protective film, and a cavity is formed between the exposed portion and an end of the second protective film adjacent to the exposed portion.

Other and further objects, features and advantages of the disclosure will appear more fully from the following description.

### BRIEF DESCRIPTION OF DRAWINGS

FIGS. 1 to 3 are diagrams illustrating a method for manufacturing a semiconductor device according to Embodiment 1.

FIG. 4 is a cross-sectional view of the semiconductor device according to Embodiment 1.

FIG. 5 is a plan view of the semiconductor device according to Embodiment 1;

FIG. 6 is a flowchart illustrating the method for manufacturing the semiconductor device according to Embodiment 1.

FIGS. 7 and 8 are enlarged views of the semiconductor device according to Embodiment 1.

FIGS. 9 and 10 are diagrams illustrating a method for manufacturing a semiconductor device according to a comparative example.

FIGS. 11 and 12 are enlarged views of the semiconductor device according to the comparative example.

FIGS. 13 and 14 are diagrams showing examples of patterning portions of a second protective film according to Embodiment 2;

FIG. 15 is a diagram illustrating a method for manufacturing a semiconductor device according to Embodiment 3.

FIG. 16 is a cross-sectional view of the semiconductor device according to Embodiment 3.

FIGS. 17 and 18 are diagrams illustrating a method for manufacturing a semiconductor device according to Embodiment 4.

FIG. 19 is a cross-sectional view of the semiconductor device according to Embodiment 4.

FIG. 20 is a flowchart illustrating the method for manufacturing the semiconductor device according to Embodiment 4.

FIGS. 21 and 22 are enlarged views of the semiconductor device according to Embodiment 4.

### DESCRIPTION OF EMBODIMENTS

A semiconductor device and a method for manufacturing thereof according to each embodiment will be described with reference to the drawings. The same or corresponding components are given the same symbols and repeated descriptions may be omitted.

### Embodiment 1

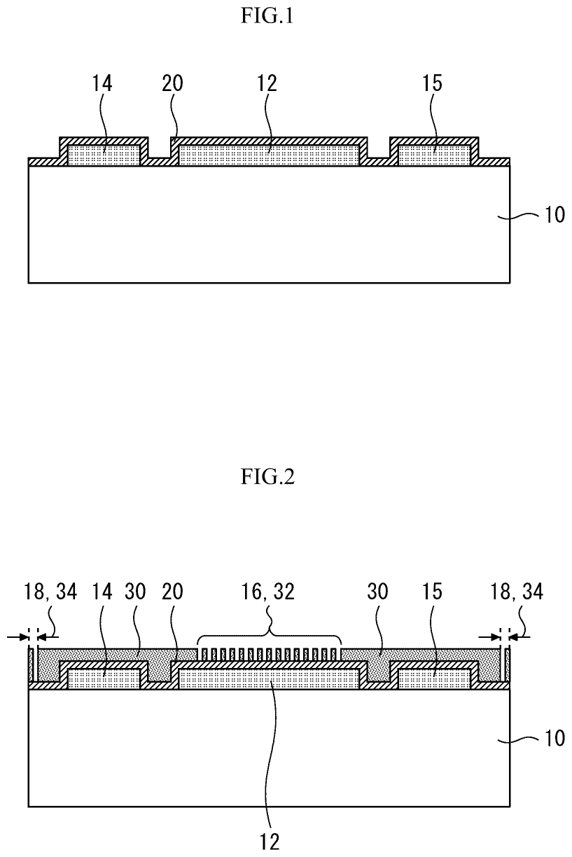

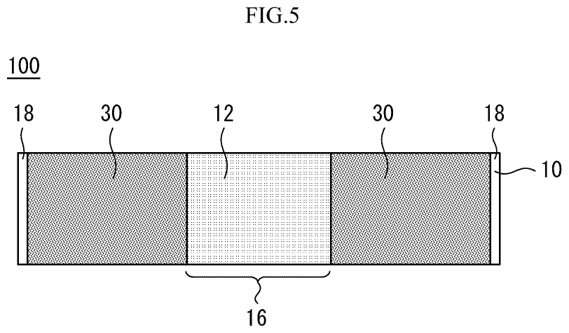

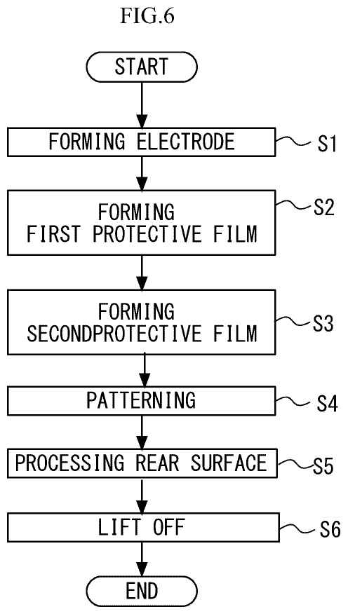

FIGS. 1-3 are diagrams illustrating a method for manufacturing a semiconductor device 100 according to Embodiment 1. FIG. 4 is a cross-sectional view of the semiconductor device 100 according to Embodiment 1. FIG. 5 is a plan view of the semiconductor device 100 according to Embodiment 1. FIG. 6 is a flowchart illustrating the method for manufacturing the semiconductor device 100 according to Embodiment 1. The method for manufacturing the semiconductor device 100 according to the present embodiment will be described with reference to FIGS. 1-6.

First, as shown in FIG. 1, electrodes 12, 14, and 15 are formed on a main surface of a semiconductor substrate 10 having the main surface and a rear surface opposite to the main surface (step 1). For example, the electrode 12 is a gate electrode, the electrode 14 is a source electrode, and the electrode 15 is a drain electrode. Various semiconductor layers are formed on the semiconductor substrate 10 in advance. Next, a first protective film 20 is formed on the electrodes 12, 14, 15 and the semiconductor substrate 10 (step 2). The first protective film 20 is, for example, a silicon oxide film or a silicon nitride film.

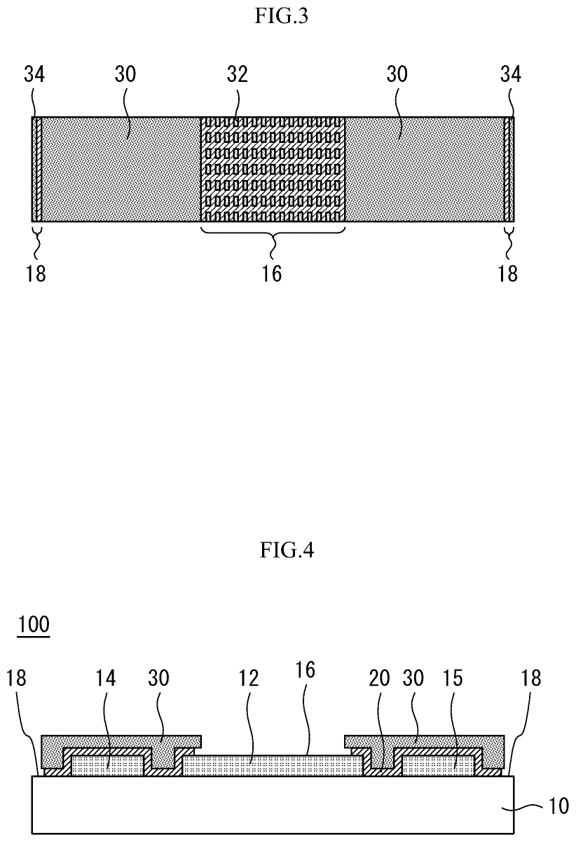

Next, a second protective film 30 is formed on the first protective film 20 (step 3). The second protective film 30 is, for example, a polyimide film or a polybenzoxazole (PBO) film. Next, as shown in FIGS. 2 and 3, a portion of the second protective film 30 is patterned to form patterned portions 32 and 34 (step 4). FIGS. 2 and 3 are a cross-sectional view and a plan view, respectively, showing a state in which a portion of the second protective film 30 has been patterned.

Here, the portion of the upper surface of the electrode 12 that is ultimately exposed from the first protective film 20 and the second protective film 30 is referred to as an exposed portion 16. In other words, the exposed portion 16 is a portion of the electrode 12. The exposed portion 16 is a portion to which wiring is bonded, for example, during product assembly. Furthermore, a portion of the main surface of the semiconductor substrate 10 that is ultimately exposed from the first protective film 20 and the second protective film 30 is called an exposed portion 18. The exposed portion 18 is formed at the chip end portion of the semiconductor substrate 10. The exposed portions 18 correspond to dicing lines in a dicing process for cutting semiconductor chips from a wafer. In this embodiment, an example in which both exposed portions 16 and 18 are formed will be described, but it is sufficient that an exposed portion is formed at least on portions of electrodes 12, 14, and 15 or on a portion of semiconductor substrate 10.

In step 4, the portions of the second protective film 30 formed directly above the exposed portions 16, 18 are patterned to partially expose the portions of the first protective film 20 formed directly above the exposed portions 16, 18 from the second protective film 30. That is, the patterned portions 32 and 34 are formed directly above the exposed portions 16 and 18, respectively. The patterning portions 32 and 34 are patterned to have a structure and dimensions that ensure the surface protection function in step 5 described below, and also allow lift-off of the second protective film 30 in step 6.

Next, after patterning the second protective film 30 (step 4), the rear surface of the semiconductor substrate 10 is processed (step 5). The rear surface of the semiconductor substrate 10 is processed without attaching a protective tape on the second protective film 30. That is, the rear surface of the semiconductor substrate 10 is processed while the main surface of the semiconductor substrate 10 is protected by the second protective film 30, which is a polyimide film or the like. The rear surface processing is performed by flipping the wafer over. The rear surface processing is, for example, grinding of the semiconductor substrate 10. The processing of the rear surface may include forming a semiconductor layer on the rear surface side, forming a rear surface electrode, and the like.

Next, after processing the rear surface of the semiconductor substrate 10, the patterned portions 32, 34 of the second protective film 30 are removed together with the portions of the first protective film 20 formed directly above the exposed portions 16, 18 (step 6). Specifically, the first protective film 20 is wet-etched using the second protective film 30 as a mask. The etching chemical is a chemical that reacts with the first protective film 20 but does not react with the second protective film 30. For example, when the first protective film 20 is made of SiO2, hydrogen fluoride can be used as the chemical solution. When the first protective film 20 is made of SiN, phosphoric acid (H3PO4) can be used as the chemical solution. As a result, the portions of the first protective film 20 directly below the patterned portions 32 and 34 are removed. Moreover, the portions of the first protective film 20 other than those directly under the patterned portions 32 and 34 are completely covered by the second protective film 30 and are therefore not etched.

At this time, the patterned portions 32 and 34 of the second protective film 30 are also removed together with the first protective film 20 directly below. That is, the patterned portions 32 and 34 of the second protective film 30 are lifted off. This allows the exposed portions 16 and 18 to be exposed from the first protective film 20 and the second protective film 30, as shown in FIGS. 4 and 5.

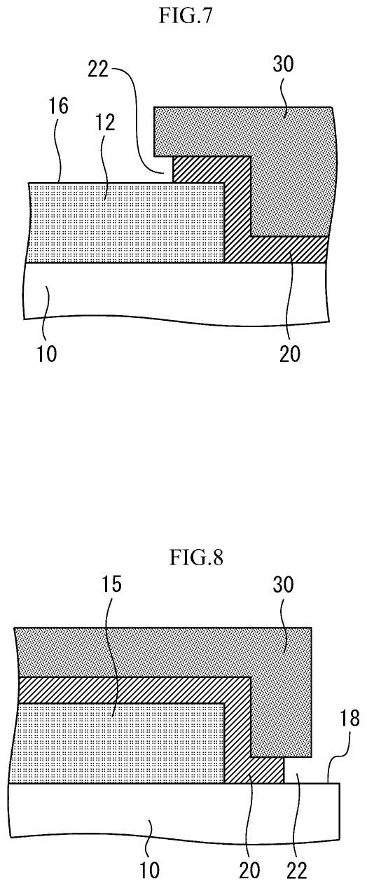

FIGS. 7 and 8 are enlarged views of the semiconductor device 100 according to Embodiment 1. FIG. 7 is an enlarged view of the end of exposed portion 16, and FIG. 8 is an enlarged view of the end of exposed portion 18. In step 6, the first protective film 20 is overetched. Therefore, a cavity 22 is formed between the exposed portion 16 and the end of the second protective film 30 adjacent to the exposed portion 16. The same applies to the exposed portion 18. In other words, the end of the first protective film 20 is recessed with respect to the end of the second protective film 30. The height of the cavity 22 is approximately the same as the thickness of the first protective film 20. In this embodiment, the end faces of the first protective film 20 adjacent to the exposed portions 16 and 18 are exposed from the second protective film 30. The depth of the cavity 22 can be controlled by patterning the second protective film 30. Although the cavity 22 is essentially created by overetching, it is possible to create a structure without the cavity 22.

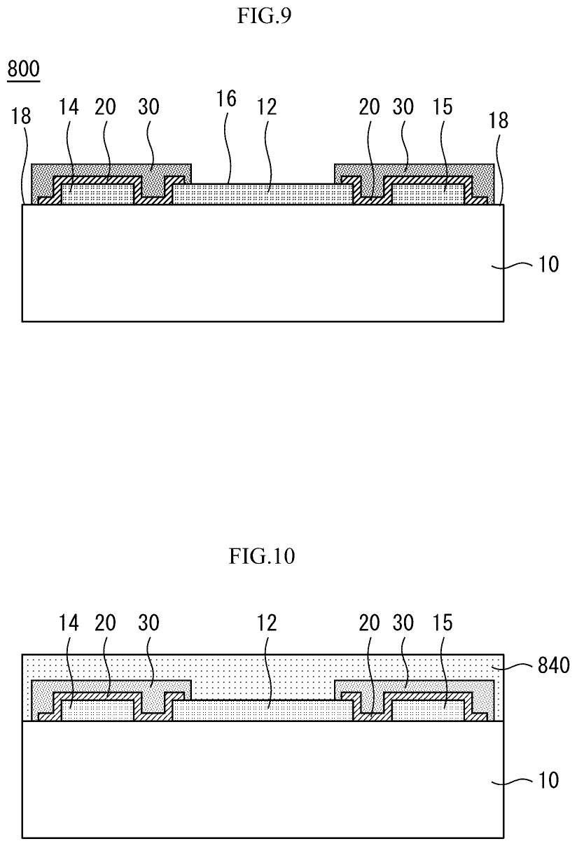

FIGS. 9 and 10 are diagrams illustrating a method for manufacturing a semiconductor device 800 according to a comparative example. FIG. 9 shows the state before the rear surface is processed. The comparative example differs from the present embodiment in that exposed portions 16 and 18 are exposed from first protective film 20 and second protective film 30 before the rear surface is processed. By covering the electrodes 14 and 15 around the electrode 12 with a protective film, it becomes possible to protect the semiconductor device 800 and maintain its withstand voltage.

Next, the rear surface of the semiconductor substrate 10 is ground to obtain the desired thickness of the semiconductor substrate 10. At this time, the surface of the semiconductor substrate 10 needs to be covered with a protective film so as not to be scratched during grinding. Here, the second protective film 30 has openings formed therein for bonding or the like. Therefore, the second protective film 30 of the comparative example does not have the function of protecting the front surface during rear surface processing. Therefore, as shown in FIG. 10, a protective tape 840 is further applied. After the processing of the rear surface, including grinding, is completed, the protective tape 840 is peeled off. This requires a process for forming the protective tape 840 and a process for removing the protective tape 840, which may increase material costs and manufacturing time.

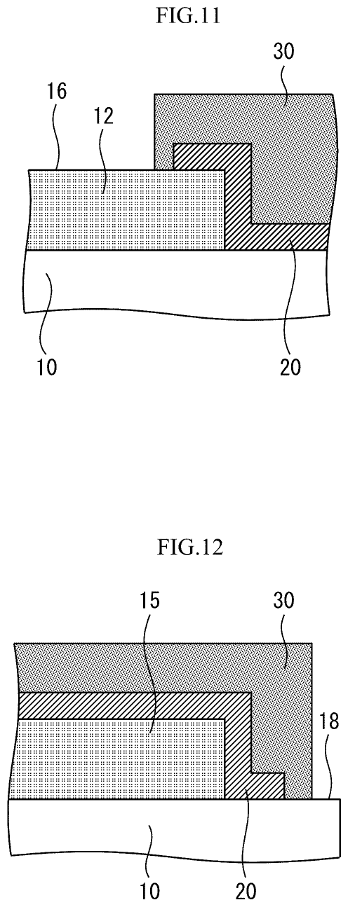

FIGS. 11 and 12 are enlarged views of a semiconductor device 800 according to a comparative example. FIG. 11 is an enlarged view of the end of exposed portion 16, and FIG. 12 is an enlarged view of the end of exposed portion 18. In the comparative example, after removing the first protective film 20 directly above the exposed portions 16 and 18, the second protective film 30 is formed, and then the second protective film directly above the exposed portions 16 and 18 is removed. In this case, the first protective film 20 is not exposed. Moreover, the cavity 22 caused by overetching as in this embodiment does not occur.

Next, the effects of this embodiment will be described. In this embodiment, the rear surface is processed in a state where the patterned portions 32 and 34 are formed in the second protective film 30. At this time, the rear surface of the semiconductor substrate 10 can be processed while protecting the main surface of the semiconductor substrate 10 with the second protective film 30. By providing the second protective film 30 with the function of protecting the wafer surface, the conventional process of forming a protective tape and the process of removing the protective tape can be omitted. Therefore, the manufacturing process can be simplified, and material costs and manufacturing time can be reduced.

As a modification of this embodiment, the structure of the semiconductor substrate 10 itself, the number of electrodes, the material of the electrode protective film, etc. can be appropriately changed. Furthermore, the semiconductor substrate 10 may be, for example, a silicon substrate, and may be made with a wide band gap semiconductor. The wide band gap semiconductor is, for example, silicon carbide, a gallium nitride based material or diamond.

The above-mentioned modifications can be appropriately applied to the methods for manufacturing a semiconductor device and the semiconductor devices according to the following embodiments. The semiconductor device and the method for manufacturing thereof according to the following embodiment have much in common with Embodiment 1, so the following description will focus on the differences from Embodiment 1.

### Embodiment 2

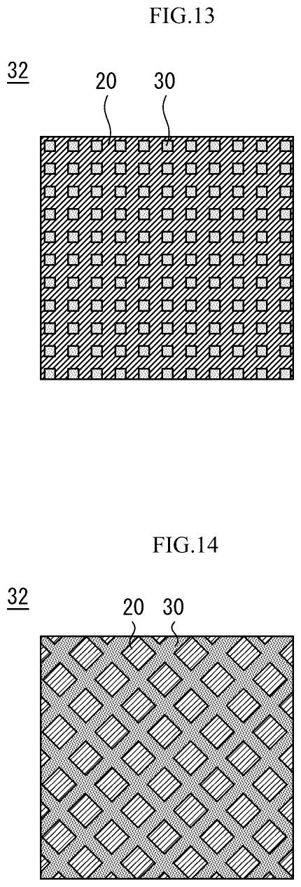

FIGS. 13 and 14 are diagrams showing examples of the patterned portion 32 of the second protective film 30 according to Embodiment 2. The patterning portion 32 needs to be formed so that the second protective film 30 can protect the front surface of the semiconductor substrate 10 when the rear surface of the semiconductor substrate 10 is processed. Furthermore, the patterned portion 32 needs to be formed so that the patterned portion 32 is completely removed during lift-off, that is, so that the chemical solution reaches the underlying first protective film 20. For this reason, the patterning portion 32 needs to be formed so that the portion of the second protective film 30 formed directly above the exposed portion 16 is partially opened.

Specifically, from the viewpoint of protecting the surface of the semiconductor substrate 10, it is preferable that the area of the first protective film 20 covered by the patterned portion 32 has a certain degree of size. From the viewpoint of lift-off, it is preferable that the area of the first protective film 20 covered by the patterned portion 32 is small. It is preferable that, for example, 10% or more of the area of the first protective film 20 directly above the exposed portion 16 be covered with the second protective film 30. It is preferable that about 50%, specifically 40% to 60%, of the area of the first protective film 20 directly above the exposed portion 16 be covered with the second protective film 30.

From the above viewpoints, it is preferable to pattern the second protective film 30 in a mesh, lattice, dot, island or stripe shape. In the example of FIG. 13, the second protective film 30 is patterned in a dot or island shape. The second protective film 30 can also be said to be columnar. In the example of FIG. 14, the second protective film 30 is patterned in a mesh or lattice shape. In the example of FIG. 14, it can be said that the linear second protective films 30 are formed so as to intersect. In this manner, the patterned portion 32 is formed by, for example, a regular arrangement of the second protective film 30. Although the patterning portion 32 has been described as an example here, a similar pattern can be applied to the patterning portion 34 as well.

### Embodiment 3

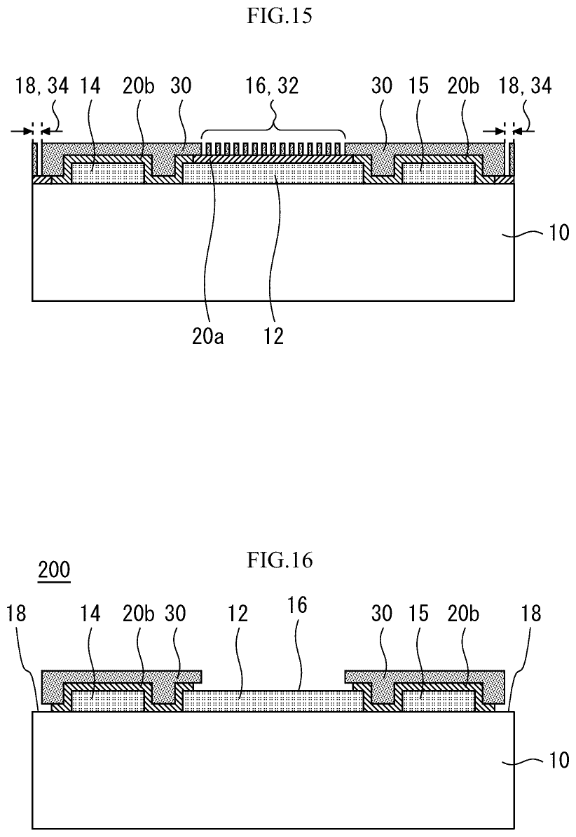

FIG. 15 is a diagram illustrating a method for manufacturing a semiconductor device according to Embodiment 3. FIG. 15 shows a state in which the patterned portion 32 is formed on the second protective film 30. The first protective film 20 has portions 20a formed directly above the exposed portions 16 and 18 and the other portions 20b made of different materials. The other configuration is the same as that of Embodiment 1. Of the first protective film 20, the portion 20 a formed directly above the exposed portions 16, 18 is, for example, a silicon oxide film, and the other portion 20b is, for example, a silicon nitride film.

In forming the first protective film 20, first, a SiN film is formed, and then the portions of the SiN film above the exposed portions 16 and 18 are removed. Thereafter, a SiO2 film is formed on the exposed portions 16 and 18.

FIG. 16 is a cross-sectional view of a semiconductor device 200 according to Embodiment 3. By the etching in step 6, the portion made of SiO2 is removed, and the portion 20 b made of SiN remains. SiN is excellent in protecting electrodes, and SiO2 is easy to remove. Therefore, in this embodiment, the exposed portions 16, 18 can be formed with high precision, and the electrodes can be reliably protected.

### Embodiment 4

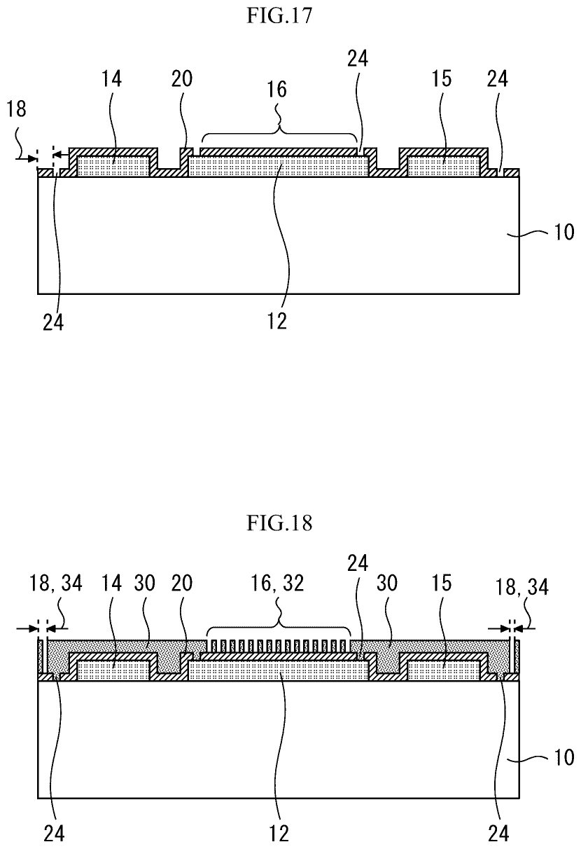

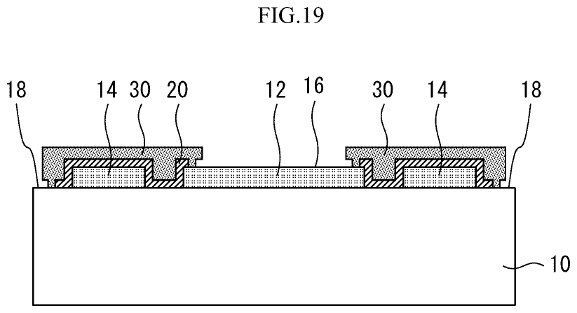

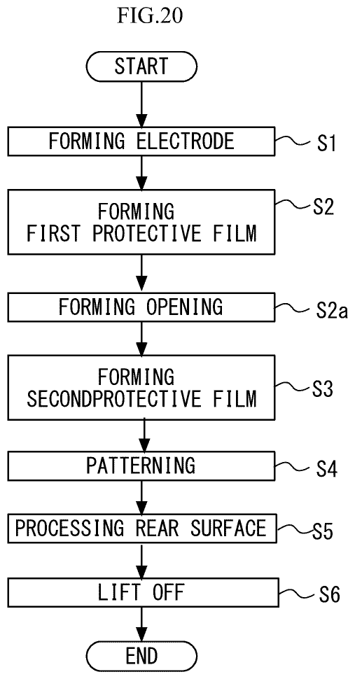

FIGS. 17 and 18 are diagrams illustrating a method for manufacturing a semiconductor device 300 according to Embodiment 4. FIG. 19 is a cross-sectional view of the semiconductor device 300 according to Embodiment 4. FIG. 20 is a flowchart illustrating the method for manufacturing the semiconductor device 300 according to Embodiment 4. Steps 1 and 2 are the same as steps 1 and 2 in Embodiment 1. In this embodiment, as shown in FIG. 17, openings 24 are formed in the first protective film 20 at positions adjacent to the portions formed directly above the exposed portions 16, 18 (step 2a). It can also be said that the openings 24 are formed at the boundaries between the exposed portions 16, 18 and the areas where the first protective film 20 is to remain. The openings 24 may be formed by etching.

Thereafter, the second protective film 30 is formed (step 3). As shown in FIG. 18, when the second protective film 30 is formed, the openings 24 are filled with the second protective film 30. That is, in the opening 24, the second protective film 30 and the electrode 12 or the semiconductor substrate 10 are in direct contact with each other. Step 4-6 is the same as step 4-6 in Embodiment 1. In addition, when removing the patterned portion of the second protective film 30 and the portion of the first protective film 20 formed directly above the exposed portions 16, 18 in step 6, the portion of the second protective film 30 that fills the opening 24 remains.

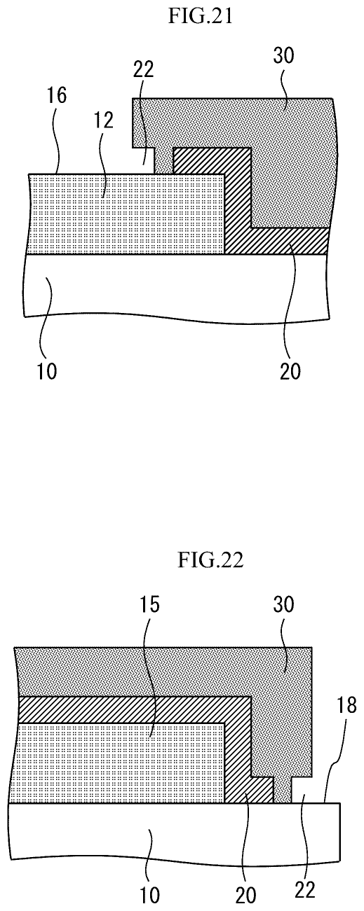

FIGS. 21 and 22 are enlarged views of a semiconductor device according to Embodiment 4. FIG. 21 is an enlarged view of the end of exposed portion 16, and FIG. 22 is an enlarged view of the end of exposed portion 18. As in Embodiment 1, in step 6, the first protective film 20 is overetched. Therefore, a cavity 22 is formed between the end of the second protective film 30 adjacent to the exposed portion 16 and the exposed portion 16. The same applies to the exposed portion 18. Furthermore, the end faces of the first protective film 20 adjacent to the exposed portions 16 and 18 are covered with a second protective film 30. The portion of the second protective film 30 that covers the end face of the first protective film 20 corresponds to the portion of the second protective film 30 that fills the opening 24.

In this embodiment, since the opening 24 is filled with the second protective film 30, over-etching of the first protective film 20 during lift-off can be suppressed. In other words, the etching of the first protective film 20 can be stopped by the portion of the second protective film 30 that fills the opening 24. Therefore, the floating of the second protective film 30 can be reduced. Moreover, the shape of the end of the second protective film 30 can be controlled, and exposure of the first protective film 20 can be prevented.

Various aspects of the present disclosure are summarized below as appendixes.

### (Appendix 1)

A method for manufacturing a semiconductor device, the method comprising:
forming an electrode on a main surface of a semiconductor substrate having the main surface and a rear surface opposite to the main surface;
forming a first protective film on the electrode and the semiconductor substrate;
forming a second protective film on the first protective film;
patterning a portion of the second protective film formed directly above an exposed portion including a portion of the electrode or a portion of the semiconductor substrate to partially expose a portion of the first protective film formed directly above the exposed portion from the second protective film;
after the patterning of the second protective film, processing the rear surface of the semiconductor substrate; and
after the processing of the rear surface of the semiconductor substrate, removing the patterned portion of the second protective film together with the portion of the first protective film formed directly above the exposed portion, to expose the exposed portion from the first protective film and the second protective film.

### (Appendix 2)

The method for manufacturing the semiconductor device according to appendix 1, wherein the processing of the rear surface is performed without applying a protective tape on the second protective film.

### (Appendix 3)

The method for manufacturing the semiconductor device according to appendix 1 or 2, wherein the exposed portion includes the portion of the electrode.

### (Appendix 4)

The method for manufacturing the semiconductor device according to any one of appendixes 1 to 3, wherein the exposed portion includes a chip end portion of the semiconductor substrate.

### (Appendix 5)

The method for manufacturing the semiconductor device according to any one of appendixes 1 to 4, wherein in the patterning, the second protective film is patterned in a mesh, lattice, dot, island or stripe shape.

### (Appendix 6)

The method for manufacturing the semiconductor device according to any one of appendixes 1 to 5, wherein the second protective film is a polyimide film or a polybenzoxazole film.

### (Appendix 7)

The method for manufacturing the semiconductor device according to any one of appendixes 1 to 6, wherein the first protective film is a silicon oxide film or a silicon nitride film.

### (Appendix 8)

The method for manufacturing a semiconductor device according to any one of appendixes 1 to 7, wherein the first protective film has a different material between the portion formed directly above the exposed portion and the other portion.

### (Appendix 9)

The method for manufacturing the semiconductor device according to appendix 8, wherein the portion of the first protective film formed directly above the exposed portion is a silicon oxide film, and the other portion of the first protective film is a silicon nitride film.

### (Appendix 10)

The method for manufacturing the semiconductor device according to any one of appendixes 1 to 9, further comprising forming an opening in the first protective film at a position adjacent to the portion of the first protective film formed directly above the exposed portion, wherein
after the forming of the opening, the forming of the second protective film is performed.

### (Appendix 11)

The method for manufacturing the semiconductor device according to appendix 10, wherein in the forming of the second protective film, the opening is filled with the second protective film, and
in the removing of the patterned portion of the second protective film and the portion of the first protective film formed directly above the exposed portion, the portion of the second protective film that fills the opening remains.

### (Appendix 12)

A semiconductor device comprising:
a semiconductor substrate having a main surface and a rear surface opposite to the main surface;
an electrode formed on the main surface of the semiconductor substrate;
a first protective film formed on the electrode and the semiconductor substrate; and
a second protective film formed on the first protective film; wherein
an exposed portion is formed in a portion of the electrode or a portion of the semiconductor substrate, the exposed portion being exposed from the first protective film and the second protective film, and
a cavity is formed between the exposed portion and an end of the second protective film adjacent to the exposed portion.

### (Appendix 13)

The semiconductor device according to appendix 12, wherein an end face of the first protective film adjacent to the exposed portion is exposed from the second protective film.

### (Appendix 14)

The semiconductor device according to appendix 12, wherein an end face of the first protective film adjacent to the exposed portion is covered with the second protective film.

### (Appendix 15)

The semiconductor device according to any one of appendixes 12 to 14, wherein the semiconductor substrate is made with a wide band gap semiconductor.

### (Appendix 16)

The semiconductor device according to appendix 15, wherein the wide band gap semiconductor is silicon carbide, a gallium nitride-based material or diamond.

In the method for manufacturing a semiconductor device according to the present disclosure, the portion of the second protective film formed directly above the exposed portion is patterned, so that the portion of the first protective film formed directly above the exposed portion is partially exposed from the second protective film. By processing the rear surface in this state, the rear surface can be processed while protecting the main surface of the semiconductor substrate with the second protective film. Therefore, there is no need to apply a protective tape, and the manufacturing process can be simplified.

The semiconductor device according to the present disclosure can be manufactured by the above-described simplified manufacturing process.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-213282, filed on Dec. 6, 2024 including specification, claims, drawings and summary, on which the Convention priority of the present application is based, are incorporated herein by reference in its entirety.

1. A method for manufacturing a semiconductor device, the method comprising:
forming an electrode on a main surface of a semiconductor substrate having the main surface and a rear surface opposite to the main surface;
forming a first protective film on the electrode and the semiconductor substrate;
forming a second protective film on the first protective film;
patterning a portion of the second protective film formed directly above an exposed portion including a portion of the electrode or a portion of the semiconductor substrate to partially expose a portion of the first protective film formed directly above the exposed portion from the second protective film;
after the patterning of the second protective film, processing the rear surface of the semiconductor substrate; and
after the processing of the rear surface of the semiconductor substrate, removing the patterned portion of the second protective film together with the portion of the first protective film formed directly above the exposed portion, to expose the exposed portion from the first protective film and the second protective film.

2. The method for manufacturing the semiconductor device according to claim 1, wherein the processing of the rear surface is performed without applying a protective tape on the second protective film.

3. The method for manufacturing the semiconductor device according to claim 1, wherein the exposed portion includes the portion of the electrode.

4. The method for manufacturing the semiconductor device according to claim 1, wherein the exposed portion includes a chip end portion of the semiconductor substrate.

5. The method for manufacturing the semiconductor device according to claim 1, wherein in the patterning, the second protective film is patterned in a mesh, lattice, dot, island or stripe shape.

6. The method for manufacturing the semiconductor device according to claim 1, wherein the second protective film is a polyimide film or a polybenzoxazole film.

7. The method for manufacturing the semiconductor device according to claim 1, wherein the first protective film is a silicon oxide film or a silicon nitride film.

8. The method for manufacturing a semiconductor device according to claim 1, wherein the first protective film has a different material between the portion formed directly above the exposed portion and the other portion.

9. The method for manufacturing the semiconductor device according to claim 8, wherein the portion of the first protective film formed directly above the exposed portion is a silicon oxide film, and the other portion of the first protective film is a silicon nitride film.

10. The method for manufacturing the semiconductor device according to claim 1, further comprising forming an opening in the first protective film at a position adjacent to the portion of the first protective film formed directly above the exposed portion, wherein
after the forming of the opening, the forming of the second protective film is performed.

11. The method for manufacturing the semiconductor device according to claim 10, wherein in the forming of the second protective film, the opening is filled with the second protective film, and
in the removing of the patterned portion of the second protective film and the portion of the first protective film formed directly above the exposed portion, the portion of the second protective film that fills the opening remains.

12. A semiconductor device comprising:
a semiconductor substrate having a main surface and a rear surface opposite to the main surface;
an electrode formed on the main surface of the semiconductor substrate;
a first protective film formed on the electrode and the semiconductor substrate; and
a second protective film formed on the first protective film; wherein
an exposed portion is formed in a portion of the electrode or a portion of the semiconductor substrate, the exposed portion being exposed from the first protective film and the second protective film, and
a cavity is formed between the exposed portion and an end of the second protective film adjacent to the exposed portion.

13. The semiconductor device according to claim 12, wherein an end face of the first protective film adjacent to the exposed portion is exposed from the second protective film.

14. The semiconductor device according to claim 12, wherein an end face of the first protective film adjacent to the exposed portion is covered with the second protective film.

15. The semiconductor device according to claim 12, wherein the semiconductor substrate is made with a wide band gap semiconductor.

16. The semiconductor device according to claim 15, wherein the wide band gap semiconductor is silicon carbide, a gallium nitride-based material or diamond.
